(19) United States
(12) Patent Application Publication
(10) Pub. No.: US 2025/0274145 A1
(43) Pub. Date: Aug. 28, 2025

(54) PILLARLESS ANTENNA STRUCTURE FOR BULK ACOUSTIC WAVE FILTER

(71) Applicant: SKYWORKS SOLUTIONS, INC., Irvine, CA (US)

(72) Inventors: Atsushi Takano, Kadoma-Shi (JP); Tomoya Komatsu, Irvine, CA (US); Ahmad Adel Ahmad Gheethan, Newbury Park, CA (US); Kshitij Sandeep Sadasivan, Sunnyvale, CA (US)

(21) Appl. No.: 19/050,355

(22) Filed: Feb. 11, 2025

Related U.S. Application Data
(60) Provisional application No. 63/558,432, filed on Feb. 27, 2024.

(51) Int. Cl. H04B 1/00; H03H 9/70; H04B 1/40

(52) U.S. Cl. CPC H04B 1/0057; H03H 9/706; H04B 1/40

(57) ABSTRACT

A duplexer including a support substrate, a reception signal terminal, a transmit signal terminal, an antenna terminal, a receive side filter formed on the support substrate and electrically coupling the reception signal terminal to the antenna terminal, a transmit side filter formed on the support substrate and electrically coupling the transmit signal terminal to the antenna terminal, a side wall surrounding the receive side filter and the transmit side filter, and a cap wafer disposed on the side wall and enclosing the receive side filter and the transmit side filter in a cavity defined by the cap wafer, the side wall, and the support substrate, there being no post disposed on the antenna terminal and in contact with the cap wafer.

### CROSS-REFERENCE TO RELATED APPLICATIONS

This application claims priority under 35 U.S.C. § 119(e) to U.S. Provisional Patent Application Ser. No. 63/558,432, titled “PILLARLESS ANTENNA STRUCTURE FOR BULK ACOUSTIC WAVE FILTER,” filed Feb. 27, 2024, the entire content of which is incorporated herein by reference for all purposes.

### BACKGROUND

Conventionally, in communication devices such as mobile phones, filtering devices are used to separate signals having different bands, such as a transmission signal and a reception signal, or transmission or reception signals, in different bands, etc. Bulk acoustic wave (BAW) resonators have been used for such filtering devices. The BAW resonators may include film bulk acoustic resonators and/or solidly mounted resonators (SMRs).

A plurality of BAW resonators may be electrically connected to form a duplexer 10 in which both transmit circuitry 20 including a transmit signal terminal 30 and receive circuitry 40 including a receive signal terminal 50 are electrically coupled to an antenna 60 as schematically illustrated in FIG. 1.

In some instances both the receive circuitry and the transmit circuitry of a duplexer are provided on a single die and formed on the same substrate. FIG. 2 is a simplified illustration of the arrangement of BAW resonators in one example of a duplexer package 100 in which the transmit and receive circuitry are in the form of ladder filters.

In the duplexer package 100, the receive circuitry includes series-connected BAW resonators 111, 113, 115, 117 disposed in series along a conductive signal path 131 extending from an antenna terminal 310 to a reception signal terminal 143 on the top surface region 420′ of a support substrate 420. Parallel-connected BAW resonators 112, 114, 116 are connected between a ground plane 132 and respective nodes interconnecting the series-connected BAW resonators 111, 113, 115, 117 along the conductive signal path 131. The ground plane 132 connects the parallel-connected BAW resonators 112, 114, 116 to ground contacts/terminals 142, 144, 146.

In the duplexer package 100, the transmit circuitry includes series-connected BAW resonators 211, 213, 215, 217 disposed in series along a conductive signal path 231 extending from the antenna terminal 310 to a transmit signal terminal 243 on the top surface region 420″ of the support substrate 420. Parallel-connected BAW resonators 212, 214, 216 are connected between a ground plane 232 and respective nodes interconnecting the series-connected BAW resonators 211, 213, 215, 217 along the conductive signal path 231. The ground plane 232 connects the parallel-connected BAW resonators 212, 214, 216 to ground contacts/terminals 242, 244, 246.

The duplexer package 100 includes a cap wafer 320 (shown in FIGS. 3-7), which may be formed from Si and is disposed to oppose the top surface regions 420′, 420″ of the support substrate 420 via a certain gap. A metal side wall 154 formed along the outer periphery on the top surface regions 420′, 420″ of the support substrate 420 spaces the cap wafer 320 apart from the support substrate 420 and encloses the gap between the support substrate 420 and the cap wafer 320. In some embodiments the side wall 154 may be grounded.

### SUMMARY

In accordance with one aspect, there is provided a duplexer. The duplexer comprises a support substrate, a reception signal terminal, a transmit signal terminal, an antenna terminal, a receive side filter formed on the support substrate and electrically coupling the reception signal terminal to the antenna terminal, a transmit side filter formed on the support substrate and electrically coupling the transmit signal terminal to the antenna terminal, a side wall surrounding the receive side filter and the transmit side filter, and a cap wafer disposed on the side wall and enclosing the receive side filter and the transmit side filter in a cavity defined by the cap wafer, the side wall, and the support substrate, a space being defined between the cap wafer and upper surface of the antenna terminal, the space being formed by an absence of a post disposed on the antenna terminal and in contact with the cap wafer.

In some embodiments, the duplexer further comprises an external antenna contact disposed on a side of the support substrate opposite the antenna terminal.

In some embodiments, the duplexer further comprises a through substrate via passing through the support substrate and electrically connecting the antenna terminal to the external antenna contact.

In some embodiments, the cap wafer is formed of silicon.

In some embodiments, a side of the cap wafer facing the support substrate include a trap-rich layer.

In some embodiments, the antenna terminal includes an adhesion layer, a first metal layer disposed on the adhesion layer, and a second metal layer disposed on the first metal layer.

In some embodiments, the second metal layer is formed of a different metal than the first metal layer.

In some embodiments, the second metal layer is at least as thick as the first metal layer.

In some embodiments, the receive side filter and the transmit side filter both include bulk acoustic wave resonators.

In some embodiments, the duplexer further comprises a post disposed on the reception signal terminal extending from the reception signal terminal to the cap wafer.

In some embodiments, the duplexer further comprises a post disposed on the transmit signal terminal and extending from the transmit signal terminal to the cap wafer.

In some embodiments, the duplexer further comprises one or more ground terminals disposed on the support substrate.

In some embodiments, the duplexer further comprises posts disposed on the one or more ground terminals and extending from the one or more ground terminals to the cap wafer.

In some embodiments, the duplexer is included in a front end module.

In some embodiments, the duplexer is included in a front end module that is included in an electronic device.

In accordance with another aspect, there is provided a method of forming a duplexer. The method comprises depositing a layer of metal including portions defining a reception signal terminal, a transmit signal terminal, and an antenna terminal on a support substrate, forming a receive side filter on the support substrate electrically coupling the reception signal terminal to the antenna terminal, forming a transmit side filter on the support substrate electrically coupling the transmit signal terminal to the antenna terminal, forming a metal side wall on the support substrate surrounding the receive side filter and the transmit side filter, and attaching a cap wafer to a top of the side wall, there being no post disposed on the antenna terminal and in contact with the cap wafer.

In some embodiments, the method further comprises forming the cap wafer from Si with a trap-rich layer on a lower side of the cap wafer.

In some embodiments, the method further comprises forming the antenna terminal from an adhesion layer, a first metal layer disposed on the adhesion layer, and a second metal layer disposed on the first metal layer.

In some embodiments, the method further comprises forming a post on the reception signal terminal extending from the reception signal terminal to the cap wafer.

In some embodiments, the method further comprises forming a post on the transmit signal terminal and extending from the transmit signal terminal to the cap wafer.

In some embodiments, the method further comprises forming one or more ground terminals on the support substrate with posts disposed on the one or more ground terminals and extending from the one or more ground terminals to the cap wafer.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a circuit diagram showing a configuration of a duplexer;

FIG. 2 is a plan view of a duplexer package including a ladder-type transmit and receive filters formed using BAW resonators;

FIG. 3 is a cross-sectional diagram of a portion of an example of a duplexer including an antenna terminal and a sidewall;

FIG. 4 illustrates a modification to the duplexer of FIG. 3 in which a portion of an adhesion layer between the antenna terminal and sidewall has been omitted;

FIG. 5 illustrates a modification to the duplexer of FIG. 3 in which a trap-rich region has been added to the cap wafer;

FIG. 6 illustrates a modification to the duplexer of FIG. 3 in which a post disposed on the antenna terminal and extending between the antenna terminal and the cap wafer has been removed;

FIG. 7 illustrates a modification to the duplexer of FIG. 3 in which both a portion of an adhesion layer between the antenna terminal and sidewall has been omitted and in which a post disposed on the antenna terminal and extending between the antenna terminal and the cap wafer has been removed;

FIG. 8 illustrates results of simulations of parasitic signal coupling between the antenna terminal and receive terminal in examples of duplexers having the structures illustrated in FIGS. 3-7.

FIG. 9 is block diagram of one example of a front end module in which a duplexer according to certain embodiments can be used; and

FIG. 10 is a block diagram of one example of a wireless device in which a duplexer according to certain embodiments can be used.

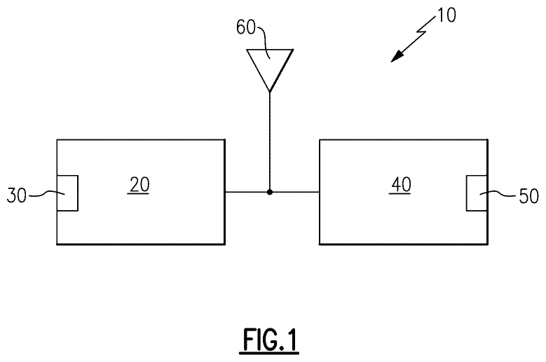

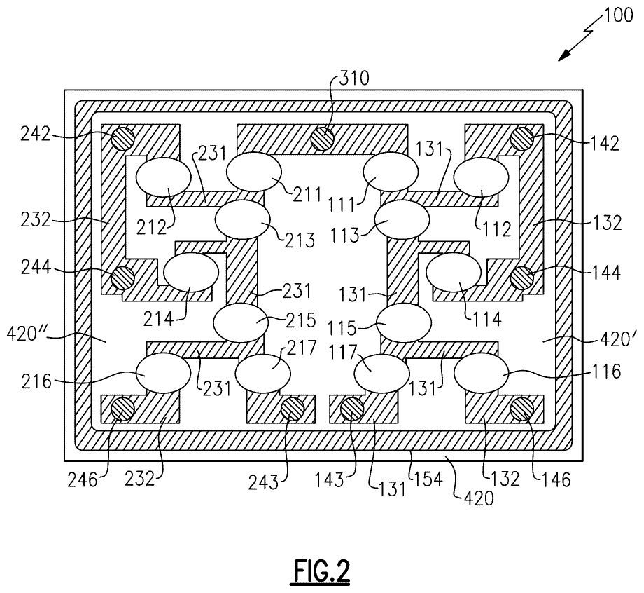

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

In a duplexer, signals within the transmit and receive circuitry are ideally fully isolated from one another so that, for example, signals input to the transmit terminal do not travel to the receive terminal. If too much transmit signal power reaches the receive terminal it could saturate a low noise amplifier coupled to the receive terminal or otherwise interfere with the receive side circuitry.

Transmit signals may travel from an antenna terminal 310 or a transmit terminal 243 of a duplexer to a receive terminal 143 of the duplexer by coupling through, for example, the side wall 154 and/or through a cap wafer 320. A post 410 that is present in many duplexer designs that extends from the antenna terminal 310 to an inner lower surface of the cap wafer 320 may provide a path for signal coupling from the antenna terminal 310 to the cap wafer 320. Signals coupled from the antenna terminal 310 to the cap wafer 320 may travel through the cap wafer 320 to other portions of the duplexer, for example, the receive terminal 143.

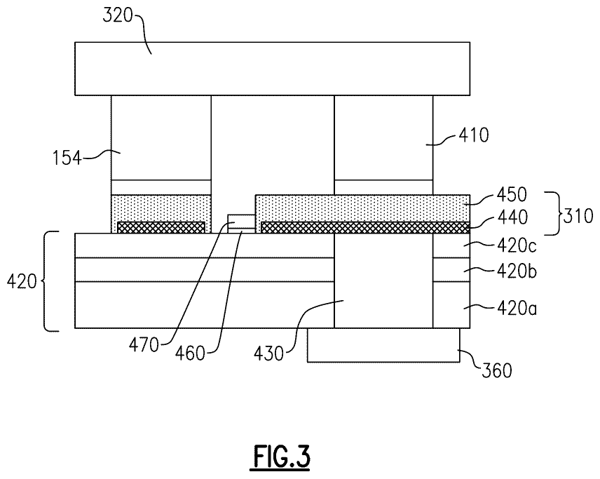

In the example of FIGS. 3-7, an external antenna contact 360 is on the outside of the device or support substrate 420 and coupled to the antenna terminal 310 by a through substrate via (TSV) 430 that passes through the device or support substrate 420. The device or support substrate 420 may be formed of a lower layer 420a of Si, a layer 420b of trap-rich Si, and an upper layer 420c of SiO₂. An upper end of the TSV 430 terminates on the antenna terminal 310 which is formed from a first metal layer 440 (e.g., Mo, Ru, or W) and a metal 1 layer 450 (e.g., Cu, Au, or Ti/Au alloy). Other portions of these metal layers 440, 450 are used to form portions of resonators in the duplexer (not shown in FIGS. 3-7.) The side wall 154 also extends from portions of the metal layers 440, 450 atop the device or support substrate 420 to the lower internal surface of the cap wafer 320. In some embodiments, portions of an adhesion layer 460 formed of, for example, Sc-doped AlN and a silicon dioxide layer 470, other portions of which are used to form portions of resonators in the duplexer, may be disposed on the device or support substrate 420 between the antenna terminal 310 and the side wall 154. Without wishing to be bound to a particular theory, it is believed that in the process of depositing the adhesion layer 460 and SiO₂ layer 470 between the antenna terminal 310 and the side wall 154, some form of conductive residue or fixed charges may be introduced onto the device or support substrate 420 between the antenna terminal 310 and the side wall 154. This residue or fixed charges may facilitate coupling of signals from the antenna terminal to the side wall 154 which may then travel through the side wall 154 and cap wafer 320 and couple to the reception signal terminal 143 of the duplexer.

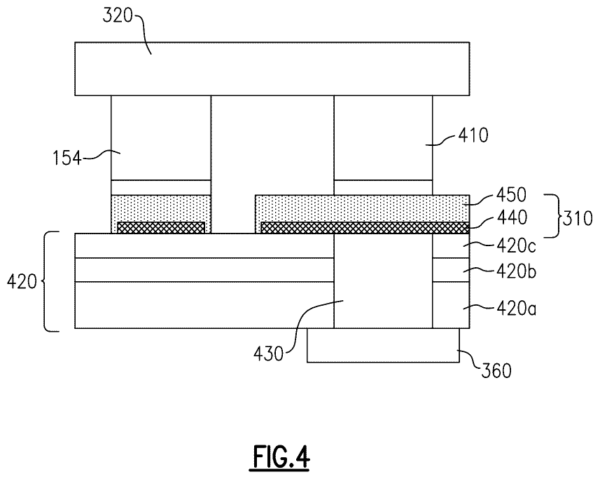

Accordingly, one way of reducing transmit signal coupling between the antenna terminal 310 or a transmit terminal 243 of a duplexer to a receive terminal 143 of the duplexer through the side wall 154 and/or cap wafer 320 may be to remove the portions of the adhesion layer 460 and oxide layer 470 between the antenna terminal 310 and sidewall 154, for example, by etching, as illustrated in FIG. 4. Alternatively, one may utilize a fabrication process that does not include forming the portions of the adhesion layer 460 and oxide layer 470 on the device or support substrate 420 between the antenna terminal 310 and the side wall 154. In some embodiments, unnecessary portions of the adhesion layer 460 and oxide layer 470 remaining between any conductive signal-carrying structures of the duplexer 100 and the sidewall 154, for example, resonators or signal lines, could be removed (or not formed in the first place) to reduce the potential for coupling between the conductive signal-carrying structures and the sidewall 154.

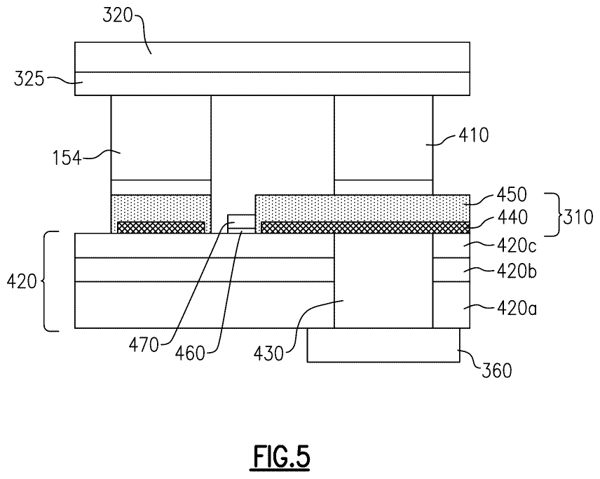

A method of further reducing transmit signal coupling between antenna terminal 310 or a transmit terminal 243 of a duplexer to a receive terminal 143 of the duplexer through the cap wafer 320 may be to increase the electrical resistance of the cap wafer 320, or at least portions contacted by the post 410 or other posts within the duplexer. This may be accomplished by forming a trap-rich layer 325 in the lower portion of the cap wafer 320 that is contacted by the post 410. An example of this is shown in FIG. 5.

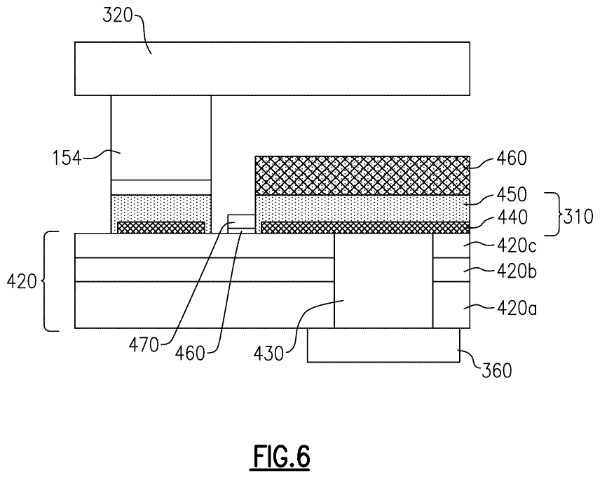

In another embodiment, reducing transmit signal coupling between antenna terminal 310 of a duplexer to a receive terminal 143 of the duplexer through the post 410 and the cap wafer 320 may be to remove the post 410, or not form the post 410 at all. The post 410 may provide mechanical support to the device or support substrate 420 and/or the cap wafer 320 so omission or removal of the post 410 may weaken the device or support substrate 420 and/or the cap wafer 320. Removal or omission of the post 410 may thus increase risk of cracking of the cap wafer 320 or device or support substrate 420 due to mechanical stress generated during manufacturing at the pick-up and transfer process from dicing tape to emboss tape or from the emboss tape to mount on a PCB. Removal or omission of the post 410 may additionally or alternatively allow for the device or support substrate 420 to undesirably flex upward toward the cap wafer 320, potentially causing a short circuit or may allow for a mismatch in thermal expansion coefficient between the TSV 430 and materials of the device or support substrate 420 to cause the device or support substrate 420 to crack. Accordingly, in some embodiments in which the post 410 is removed or is not present, an additional metal layer 460 may be provided on top of or as a portion of the antenna terminal 310 to add additional strength to the device or support substrate 420 in the region where the post 410 would otherwise have been disposed. An example of this is shown in FIG. 6. The additional metal layer 460 may be formed from the metal 2 layer of the duplexer 100 and may be as thick as or thicker than the metal 1 layer 450. The metal 1 layer 450 may be, for example, a 0.6-0.7 μm thick layer of a Ti/Au alloy and the additional metal layer 460 may be a 2 μm thick layer of copper, although aspects and embodiments disclosed herein are not limited to metal layers formed of these materials or with these thicknesses.

In some embodiments there is no post 410 disposed on the antenna terminal 310, although posts similar to post 410 may be disposed on any or all of the transmit terminal 243, receive terminal 143, or ground contacts/terminals 142, 144, 146, 242, 244, 246 to enhance the mechanical strength of the duplexer module 100.

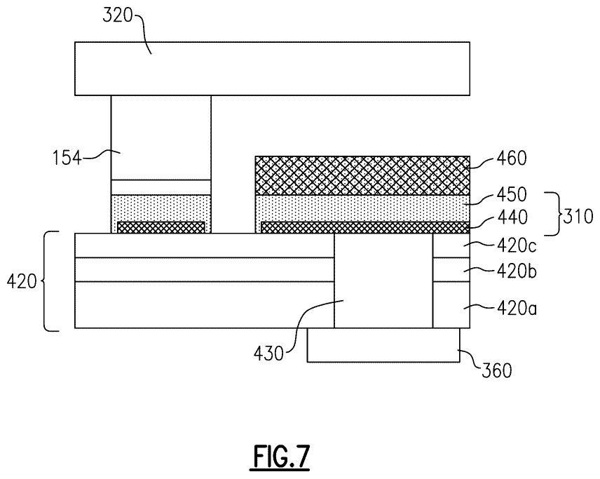

Any of the structural modifications to the duplexer illustrated in FIGS. 4-6 may be combined. For example, one may remove or omit both the portions of the adhesion layer 460, layer, and the post 410 and add the additional metal layer 460. An example of this is illustrated in FIG. 7.

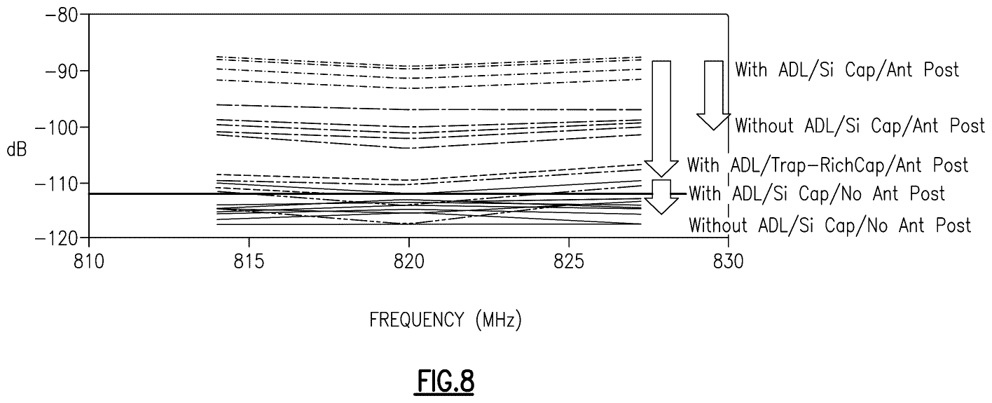

Simulations were performed to determine the effect of the structural modifications to a duplexer as illustrated in FIGS. 4-7 on parasitic coupling between the antenna terminal of the duplexer and the receive terminal, specifically parasitic coupling of the third harmonic (H3) of the transmit signal in a duplexer operating at the WiFi 2.4 band. FIG. 8 illustrates results of these simulations. As shown in FIG. 8 a duplexer with the structure shown in FIG. 3 including the portions of the adhesion layer 460 and SiO₂ layer 470 with a Si cap wafer (no trap-rich layer) 320, and including the post 410 on the antenna terminal (the “With ADL/Si Cap/Ant Post” test results) exhibited a parasitic coupling of the H3 signal between the antenna terminal 310 and receive terminal with a signal strength of about −90 db. In the embodiment illustrated in FIG. 4 in which the portions of the adhesion layer 460 and SiO₂ layer between the antenna terminal 310 and sidewall 154 was removed (the “Without ADL/Si Cap/Ant Post” test results) the parasitic coupling of the H3 signal between the antenna terminal 310 and receive terminal had a signal strength of about −100 db. In both the embodiment of FIG. 5 in which the cap wafer 320 included a trap-rich layer 325 (the “With ADL/Trap-Rich Cap/Ant Post” test results) and the embodiment of FIG. 6 in which the antenna terminal post 410 was omitted (the “With ADL/Si Cap/No Ant Post” test results) the parasitic coupling of the H3 signal between the antenna terminal 310 and receive terminal had a signal strength of about −110 db. In the embodiment of FIG. 7 in which the portions of the adhesion layer 460 and SiO₂ layer 470 and the antenna terminal post 410 were omitted (the “Without ADL/Si Cap/No Ant Post” test results) the parasitic coupling of the H3 signal between the antenna terminal 310 and receive terminal had a signal strength of about −115 db. These results show that the most effective manner to reduce parasitic coupling of transmit signals from an antenna terminal to a receive terminal through the cap wafer in a duplexer as disclosed herein operating in the WiFi 2.4 band would be to omit each of the portions of the adhesion layer 460 and SiO₂ layer identified above and the antenna terminal post 410.

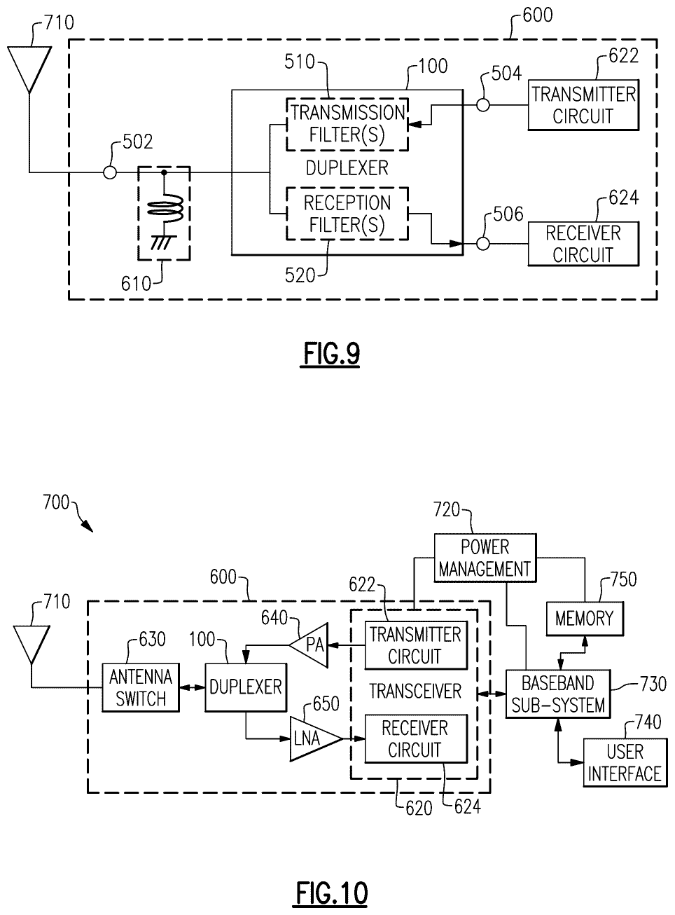

Embodiments of the duplexer 100 can be used in a wide variety of electronic devices and components. Referring to FIG. 9 there is illustrated a block diagram of one example of a front-end module 600, which may be used in an electronic device such as a wireless communications device (e.g., a mobile phone) for example, and which includes an antenna duplexer 100 as disclosed herein. The antenna duplexer 100 has a common terminal 502, an input terminal 504, and an output terminal 506. The antenna duplexer 100 may include one or more transmission filters 510 connected between the input terminal 504 and the common terminal 502, and one or more reception filters 520 connected between the common terminal 502 and the output terminal 506. An antenna 710 is connected to the common terminal 502. In certain examples, a phase matching component 610, such as an inductor, can be connected to the common terminal 502, as shown. The front-end module 600 further includes a transmitter circuit 622 connected to the input terminal 504 of the duplexer 100 and a receiver circuit 624 connected to the output terminal 506 of the duplexer 100. The transmitter circuit 622 can generate signals for transmission via the antenna 710, and the receiver circuit 624 can receive and process signals received via the antenna 710. In some embodiments such reception and transmission functionalities can be implemented in separate components, as illustrated in FIG. 9, or in a common transceiver circuit/module, as discussed further below. As will be appreciated by those skilled in the art, given the benefit of this disclosure, the front-end module 600 may include other components, not illustrated, such as, but not limited to, switches, electromagnetic couplers, amplifiers, processors, and the like.

Embodiments of the antenna duplexer 100 or front end module 600 may be advantageously used in a variety of electronic devices. Examples of the electronic devices can include, but are not limited to, consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), an appliance, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a peripheral device, a wrist watch, a clock, etc. Further, the electronic devices can include unfinished products.

FIG. 10 is a block diagram of one example of a wireless device 700 including an antenna duplexer 100 as disclosed herein. The wireless device 700 can be a cellular phone, smart phone, tablet, modem, communication network or any other portable or non-portable device configured for voice or data communication. The wireless device 700 can receive and transmit signals from the antenna 710. The wireless device 700 includes the front-end module 600, which includes the duplexer 100 as discussed above. The front-end module 600 further includes an antenna switch 630, which can be configured to switch between different frequency bands or modes, such as transmit and receive modes, for example. In the example illustrated in FIG. 10, the antenna switch 630 is positioned between the duplexer 100 and the antenna 710; however, in other examples the duplexer 100 can be positioned between the antenna switch 630 and the antenna 710, or the antenna switch 630 and the duplexer 100 can be integrated into a single module.

The front end module 600 includes a transceiver 620 that is configured to generate signals for transmission or to process received signals. The transceiver 620 can include the transmitter circuit 622 which can be connected to the input terminal 504 of the duplexer 100, and the receiver circuit 624 which can be connected to the output terminal 506 of the duplexer 100, as shown in FIG. 9. Signals generated for transmission by the transmitter circuit 622 are received by a power amplifier (PA) module 640, which amplifies the generated signals from the transceiver 620. As will be appreciated by those skilled in the art, the power amplifier module 640 can include one or more power amplifiers. The power amplifier module 640 can be used to amplify a wide variety of RF or other frequency-band transmission signals. For example, the power amplifier module 640 can receive an enable signal that can be used to pulse the output of the power amplifier to aid in transmitting a wireless local area network (WLAN) signal or any other suitable pulsed signal. The power amplifier module 640 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier module 640 and associated components including switches and the like can be fabricated on GaAs substrates using, for example, pHEMT or BiFET transistors, or on a Silicon substrate using CMOS transistors. The front-end module 600 further includes a low noise amplifier module 650, which amplifies received signals from the antenna 710 and provides the amplified signals to the receiver circuit 624 of the transceiver 620.

The wireless device 700 of FIG. 10 further includes a power management sub-system 720 that is connected to the transceiver 620 and that manages the power for the operation of the wireless device. The power management system 720 can also control the operation of a baseband sub-system 730 and other components of the wireless device 700. The power management system 720 can include, or can be connected to, a battery (not shown) that supplies power for the various components of the wireless device 700. The power management system 720 can further include one or more processors or controllers that can control the transmission of signals, for example.

In one embodiment, the baseband sub-system 730 is connected to a user interface 740 to facilitate various input and output of voice or data provided to and received from the user. The baseband sub-system 730 can also be connected to a memory 750 that is configured to store data or instructions to facilitate the operation of the wireless device 700, or to provide storage of information for the user.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, it is to be appreciated that embodiments discussed herein are not limited in application to the details of construction and the arrangement of components set forth in the description or illustrated in the accompanying drawings. The devices disclosed herein are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Accordingly, the foregoing description and drawings are by way of example only, and the scope of the invention should be determined from proper construction of the appended claims, and their equivalents.

What is claimed is:

1. A duplexer comprising:
a support substrate;
a reception signal terminal;
a transmit signal terminal;
an antenna terminal;
a receive side filter formed on the support substrate and electrically coupling the reception signal terminal to the antenna terminal;
a transmit side filter formed on the support substrate and electrically coupling the transmit signal terminal to the antenna terminal;
a side wall surrounding the receive side filter and the transmit side filter; and
a cap wafer disposed on the side wall and enclosing the receive side filter and the transmit side filter in a cavity defined by the cap wafer, the side wall, and the support substrate, a space being defined between the cap wafer and upper surface of the antenna terminal, the space being formed by an absence of a post disposed on the antenna terminal and in contact with the cap wafer.

2. The duplexer of claim 1 further comprising an external antenna contact disposed on a side of the support substrate opposite the antenna terminal.

3. The duplexer of claim 2 further comprising a through substrate via passing through the support substrate and electrically connecting the antenna terminal to the external antenna contact.

4. The duplexer of claim 1 wherein the cap wafer is formed of silicon.

5. The duplexer of claim 4 wherein a side of the cap wafer facing the support substrate include a trap-rich layer.

6. The duplexer of claim 1 wherein the antenna terminal includes an adhesion layer, a first metal layer disposed on the adhesion layer, and a second metal layer disposed on the first metal layer.

7. The duplexer of claim 6 wherein the second metal layer is formed of a different metal than the first metal layer.

8. The duplexer of claim 6 wherein the second metal layer is at least as thick as the first metal layer.

9. The duplexer of claim 1 wherein the receive side filter and the transmit side filter both include bulk acoustic wave resonators.

10. The antenna duplexer of claim 1 further comprising a post disposed on the reception signal terminal extending from the reception signal terminal to the cap wafer.

11. The antenna duplexer of claim 10 further comprising a post disposed on the transmit signal terminal and extending from the transmit signal terminal to the cap wafer.

12. The antenna duplexer of claim 11 further comprising one or more ground terminals disposed on the support substrate.

13. The antenna duplexer of claim 12 further comprising posts disposed on the one or more ground terminals and extending from the one or more ground terminals to the cap wafer.

14. A front end module including the duplexer of claim 1.

15. An electronic device including the front end module of claim 14.

16. A method of forming a duplexer, the method comprising:
depositing a layer of metal including portions defining a reception signal terminal, a transmit signal terminal, and an antenna terminal on a support substrate;
forming a receive side filter on the support substrate electrically coupling the reception signal terminal to the antenna terminal;
forming a transmit side filter on the support substrate electrically coupling the transmit signal terminal to the antenna terminal;
forming a metal side wall on the support substrate surrounding the receive side filter and the transmit side filter; and
attaching a cap wafer to a top of the side wall, there being no post disposed on the antenna terminal and in contact with the cap wafer.

17. The method of claim 16 further comprising forming the cap wafer from Si with a trap-rich layer on a lower side of the cap wafer.

18. The method of claim 16 further comprising forming the antenna terminal from an adhesion layer, a first metal layer disposed on the adhesion layer, and a second metal layer disposed on the first metal layer.

19. The method of claim 16 further comprising forming a post on the reception signal terminal extending from the reception signal terminal to the cap wafer and forming a post on the transmit signal terminal and extending from the transmit signal terminal to the cap wafer.

20. The method of claim 16 further comprising forming one or more ground terminals on the support substrate with posts disposed on the one or more ground terminals and extending from the one or more ground terminals to the cap wafer.
